(19) United States
(12) Patent Application Publication
(10) Pub. No.: US 2026/0157047 A1
(43) Pub. Date: Jun. 4, 2026

(54) ARRAY SUBSTRATE, DISPLAY PANEL, AND DISPLAY APPARATUS

(71) Applicants: Visionox Technology Inc., Kunshan (CN); Hefei Visionox Electronics Co., Ltd., Hefei (CN); Hefei Visionox Technology Co., Ltd., Hefei (CN)

(72) Inventors: Liusong NI, Hefei (CN); Pengle DANG, Kunshan (CN); Bowen YANG, Hefei (CN); Chung-Chun LEE, Kunshan (CN); Jen-Yu LEE, Hefei (CN); Yi-Yu LAI, Hefei (CN); Murong XUE, Hefei (CN); Xingfeng REN, Hefei (CN); Xiaosuo MA, Hefei (CN); Zhenhai YUE, Hefei (CN); Xuewan ZHANG, Hefei (CN)

(73) Assignees: Visionox Technology Inc., Kunshan (CN); Hefei Visionox Electronics Co., Ltd., Hefei (CN); Hefei Visionox Technology Co., Ltd., Hefei (CN)

(21) Appl. No.: 19/396,226

(22) Filed: Nov. 20, 2025

(30) Foreign Application Priority Data
Nov. 30, 2024 (CN) 202411755476.6

(51) Int. Cl. H10K 59/122; H10K 59/80

(52) U.S. Cl. CPC H10K 59/122; H10K 59/873

(57) ABSTRACT

The present application provides an array substrate, a display panel, and a display apparatus, where the array substrate includes a substrate and an isolation structure, the isolation structure is arranged on a side of the substrate, and the isolation structure includes an isolation body and a blocking portion arranged in a stacked manner, where the blocking portion is located on a side of the isolation body away from the substrate, and the isolation body and the blocking portion meet the following relation: h1/L1≥0.1, where h1 is a dimension of the blocking portion in a direction perpendicular to a surface of the substrate; and L1 is a dimension of the blocking portion protruding from the isolation body in a direction parallel to a contact surface between the blocking portion and the isolation body. In present application, the structural stability of the isolation body and the blocking portion is greater.

### CROSS-REFERENCE TO RELATED APPLICATIONS

The present application claims priority to the Chinese Patent Application No. 202411755476.6, filed on Nov. 30, 2024, and the entire contents of the aforementioned application are hereby incorporated by reference in its entirety.

### FIELD

The present application relates to the field of display devices, and in particular to an array substrate, a display panel, and a display apparatus.

### BACKGROUND

With the development of display technology, Organic Light Emitting Diode display panels are widely used due to advantages of thinness, high brightness, low power consumption, fast response, high clarity, and the like.

In the processing and manufacturing process of the display panels in the related art, there is a problem that film layers are susceptible to deformation, which affects the subsequent processing process, and even affects the display effects of the display panels.

### SUMMARY

In view of this, embodiments of the present application provide an array substrate, a display panel, and a display apparatus to solve the problem that film layers in current display panels are susceptible to deformation, which affects the subsequent processing process, and even affects the display effects of the display panels.

An embodiment of the present application provides an array substrate, including: a substrate; and an isolation structure arranged on a side of the substrate, the isolation structure enclosing isolation openings, and the isolation structure including an isolation body and a blocking portion arranged in a stacked manner, where the blocking portion is located on a side of the isolation body away from the substrate, an orthographic projection of the isolation body on the substrate is located within an orthographic projection of the blocking portion on the substrate, and the isolation body and the blocking portion meet the following relation: h1/L1≥0.1, where h1 is a dimension of the blocking portion in a direction perpendicular to a surface of the substrate; and L1 is a dimension of the blocking portion protruding from the isolation body on a contact surface between the blocking portion and the isolation body.

In the array substrate described above, the isolation body and the blocking portion in the isolation structure are made to meet the above-mentioned relation, and a thickness of the blocking portion is relatively large, while a length of the blocking portion protruding from the isolation body is relatively small, and the structural stability of the isolation body and the blocking portion is greater. This can effectively avoid deformation of the blocking portion in subsequent processing processes, and the structure of the isolation openings enclosed by the isolation structure is more stable, to prevent the display effect from being affected by the deformation of film layers.

In one embodiment, the isolation body and the blocking portion meet the following relation: h1/L1≤2; and/or the dimension L1 of the blocking portion protruding from the isolation body on the contact surface between the blocking portion and the isolation body is less than or equal to 1 μm. Such setting facilitates the processing and manufacturing of the isolation structure while meeting the structural stability of the isolation body and the blocking portion.

In one embodiment, the dimension h1 of the blocking portion in the direction perpendicular to the surface of the substrate is greater than or equal to 0.1 μm. In one embodiment, the dimension h1 of the blocking portion is less than or equal to 0.5 μm. In this way, the thickness of the blocking portion is set within a reasonable range, which can avoid the deformation of the blocking portion during subsequent processing processes, and facilitate processing and manufacturing at the same time.

In one embodiment, the isolation structure further includes a base portion, the base portion is located on a side of the isolation body close to the substrate, and the orthographic projection of the isolation body on the substrate is located within an orthographic projection of the base portion on the substrate. Such a design can further improve the isolation performance of the isolation structure.

In one embodiment, the dimension of the blocking portion tends to decrease in a direction from the isolation body to the blocking portion. Setting the blocking portion to the above shape facilitates the subsequent processing and manufacturing of the film layers.

In one embodiment, the blocking portion includes a top surface, a bottom surface, and side wall surfaces, wherein the top surface and the bottom surface are arranged opposite each other and spaced apart, the side wall surfaces are connected to the top surface and the bottom surface, an orthographic projection of the top surface on the substrate is located within an orthographic projection of the bottom surface on the substrate, and the blocking portion meets the following relation: 70°≤α≤90°, where α is an included angle between the bottom surface and the side wall surface. The included angle α between the bottom surface and the side wall surface of the blocking portion is set to meet the above range, and the ratio of the length and the thickness of the blocking portion can be reasonably controlled, and thus the length and the thickness are both within reasonable ranges.

In one embodiment, the array substrate further includes a pixel defining layer arranged on a side of the isolation structure close to the substrate, the pixel defining layer defines a plurality of pixel openings arranged spaced from each other, the pixel openings communicate with the isolation openings, and light-emitting units are arranged corresponding to the pixel openings. The pixel defining layer is disposed and the light-emitting units can be arranged to avoid signal crosstalk between adjacent light-emitting units.

In one embodiment, a distance L2 between an edge of an orthographic projection of the pixel defining layer on the substrate and an edge of the orthographic projection of the blocking portion on the substrate is greater than or equal to 1 μm. The edge of the orthographic projection of the pixel defining layer on the substrate and the edge of the orthographic projection of the blocking portion on the substrate are set to meet the above relation, and the pixel defining layer and the isolation structure have a hierarchical arrangement in a direction parallel to the surface of the substrate, which can enhance the overall structural strength of the array substrate.

In one embodiment, the isolation structure and the pixel defining layer meet the following relation: h2≥1 μm, where h2 is a distance between a surface of the pixel defining layer close to the substrate and the bottom surface of the blocking portion in the direction perpendicular to the surface of the substrate. With such setting, a distance between the pixel defining layer and the blocking portion is relatively large, which is conducive to enhancing the structural stability of the isolation structure.

In one embodiment, the blocking portion includes a main body portion and a protruding portion, where the main body portion is arranged on a side of the isolation body away from the substrate, the protruding portion protrudes from the isolation body in a direction close to the isolation openings relative to the main body portion, and a distance between the main body portion and the substrate is equal to a distance between the protruding portion and the substrate. With such an arrangement, the main body portion and the protruding portion of the blocking portion are arranged on a plane equidistant from the substrate, and the structure of the blocking portion is flatter and more integral, which is conducive to enhancing the structural strength of the blocking portion.

An embodiment of the present application provides an array substrate, including: a substrate; and an isolation structure arranged on a side of the substrate, the isolation structure enclosing isolation openings, and the isolation structure including an isolation body and a blocking portion arranged in a stacked manner, where the blocking portion is located on a side of the isolation body away from the substrate, and an orthographic projection of the isolation body on the substrate is located within an orthographic projection of the blocking portion on the substrate, where the dimension h1 of the blocking portion in the direction perpendicular to the surface of the substrate is greater than or equal to 0.1 μm.

In the array substrate described above, the blocking portion in the isolation structure is made to meet the above-mentioned relation, and a thickness of the blocking portion may be relatively large, and the structural stability of the blocking portion is greater. This can effectively avoid deformation of the blocking portion in subsequent processing processes, and the structure of the isolation openings enclosed by the isolation structure is more stable, to prevent the display effect from being affected by the deformation of film layers.

In one embodiment, the dimension h1 of the blocking portion in the direction perpendicular to the surface of the substrate is less than or equal to 0.5 μm. In this way, the thickness of the blocking portion is set within a reasonable range, which can avoid the deformation of the blocking portion during subsequent processing processes, and facilitate processing and manufacturing at the same time.

In one embodiment, the isolation body and the blocking portion meet the following relation: h1/L1≥0.1, where L1 is a distance between an edge of an orthographic projection of a surface of the blocking portion close to the isolation body on the substrate and an edge of an orthographic projection of a surface of the isolation body close to the blocking portion on the substrate. With such setting, the thickness of the blocking portion is relatively large, while a length of the blocking portion protruding from the isolation body is relatively small, and the structural stability of the isolation body and the blocking portion is greater. This can effectively avoid deformation of the blocking portion during subsequent processing processes.

An embodiment of the present application provides a display panel, including: the array substrate described above; and a light-emitting layer arranged on a side of the array substrate, where the light-emitting layer includes a plurality of light-emitting units spaced apart from each other, and the light-emitting units are arranged corresponding to the isolation openings.

In the display panel described above, the isolation body and the blocking portion in the isolation structure of the array substrate are made to meet the above-mentioned relation, to effectively avoid deformation of the blocking portion in subsequent processing processes, and the structure of the isolation openings enclosed by the isolation structure is more stable, which facilitates the manufacturing of the light-emitting units, and prevents the display effect from being affected by the deformation of the film layers.

In one embodiment, the light-emitting layer includes a first light-emitting unit, a second light-emitting unit, and a third light-emitting unit; and values of h1/L1 in an isolation structure are different from each other on a side of the first light-emitting unit, on a side of the second light-emitting unit, and on a side of the third light-emitting unit. In such a design, the values of h1/L1 in the isolation structure are set for the first light-emitting unit, the second light-emitting unit, and the third light-emitting unit, respectively, and this design has good applicability.

In one embodiment, the light-emitting unit includes a first electrode, a light-emitting portion, and a second electrode that are sequentially arranged in a stacked manner, and at least part of the first electrode is exposed from the pixel opening; and an orthographic projection of the first electrode on the substrate at least partially overlaps the orthographic projection of the isolation body on the substrate. This design, in which the first electrode of the light-emitting unit extends to a position below the isolation body, can enhance the tightness of the connection between the light-emitting units.

In one embodiment, the display panel further includes an encapsulation layer arranged on a side of the light-emitting layer away from the substrate, the encapsulation layer includes a plurality of encapsulation units, and the encapsulation unit is arranged corresponding to at least one of the light-emitting units. The encapsulation layer is arranged and the encapsulation units can provide a better encapsulation effect on the isolation openings and improve resistance of the encapsulation layer to moisture, which can avoid a problem that intrusion of moisture through the encapsulation layer into the interior of the display panel causes encapsulation failure, and can thus avoid dark spots in the display panel and improve the display effect of the display panel.

In one embodiment, the encapsulation unit includes a body portion and an extension portion connected to each other, the body portion covers a surface of a side of the light-emitting unit away from the substrate, the extension portion extends at least partially to a surface of a side of the blocking portion away from the substrate, and an orthographic projection of the extension portion on the substrate at least partially overlaps the orthographic projection of the isolation body on the substrate. In this way, the body portion of the encapsulation unit can encapsulate the light-emitting unit, and the extension portion of the encapsulation unit can encapsulate the gap between the light-emitting unit and the isolation structure, which enhances the tightness of the encapsulation unit.

In one embodiment, an orthographic projection of the first electrode on the substrate is located within an orthographic projection of the encapsulation unit on the substrate. With such setting, the first electrode of the light-emitting unit can also be completely covered by the encapsulation unit, which can avoid intrusion of moisture into the light-emitting unit.

In one embodiment, the display panel further includes a protective layer arranged on a side of the blocking portion away from the substrate. The protective layer is arranged on the side of the blocking portion away from the substrate, and the blocking portion can be pressed hard, further avoiding deformation of the blocking portion.

An embodiment of the present application provides a display apparatus, including: the display panel described above.

It should be understood that for the beneficial effects of the embodiments, reference may be made to the relevant description of the embodiments, which will not be repeated herein.

### BRIEF DESCRIPTION OF THE DRAWINGS

To describe the embodiments of the present application more clearly, the following briefly describes the accompanying drawings required for describing the embodiments or the prior art. Apparently, the accompanying drawings in the following description show merely some embodiments of the present application.

FIG. 1 is a top view of an overall structure of a display panel according to an embodiment of the present application;

FIG. 2 is a sectional view of a structure obtained through sectioning a display panel along k-k in FIG. 1 according to an embodiment of the present application;

FIG. 3 is a schematic partial enlarged view of a display panel at A in FIG. 2 according to an embodiment of the present application;

FIG. 4 is a schematic enlarged view of a blocking portion of an isolation structure in a display panel according to an embodiment of the present application;

FIG. 5 is a sectional view of a structure obtained through sectioning a display panel along k-k in FIG. 1 according to another embodiment of the present application; and

FIG. 6 is a schematic diagram of an overall structure of a display apparatus according to an embodiment of the present application.

### REFERENCE NUMERALS

10: display device;
100: display panel;
110: substrate;
120: isolation structure; 121: isolation opening; 122: isolation body; 123: blocking portion; 1231: top surface; 1232: bottom surface; 1233: side wall surface; 124: base portion;
130: light-emitting layer; 131: light-emitting unit; 1311: first electrode; 1312: light-emitting portion; 1313: second electrode; 131A: first light-emitting unit; 131B: second light-emitting unit; 131C: third light-emitting unit;

140: pixel defining layer; 141: pixel opening;

150: encapsulation layer; 151: encapsulation unit; 1511: body portion; 1512: extension portion.

### DETAILED DESCRIPTION OF THE EMBODIMENTS

In the following description, specific details, such as specific system structures, techniques, and the like are set forth for purposes of illustration and not for limitation, for a thorough understanding of the embodiments of the present application. However, it will be apparent in the art that the present application may be practiced in other embodiments without these specific details. In other cases, detailed descriptions of well-known systems, apparatuses, circuits, and methods are omitted not to obscure the description of the present application with unnecessary details.

It should be understood that the term “and/or” used in the specification and the appended claims of the present application indicates any combination and all possible combinations of one or more items listed in association, and includes the combinations.

It should be noted that when an element is referred to as being “fixed to” or “arranged at” another element, it may be directly or indirectly on the another element. When an element is referred to as being “connected to” another element, it may be directly or indirectly connected to the another element.

It should be understood that the orientation or position relationships indicated by the terms “length”, “width”, “upper”, “lower”, “front”, “rear”, “left”, “right”, “vertical”, “horizontal”, “top”, “bottom”, “inner”, “outer”, etc. are the orientation or position relationships shown in the drawings, and are only for the convenience of describing the present application and simplifying the description, rather than indicating or implying that an apparatus or an element referred to must have a specific orientation or be constructed and operated in a specific orientation, and therefore should not be construed as limiting the present application.

In addition, in the description of the specification and the appended claims of the present application, the terms “first”, “second”, “third”, etc. are used only for distinguishing description and should not be construed as indicating or implying relative importance.

Reference to “one embodiment”, “some embodiments”, etc., described in the specification of the present application means that one or more embodiments of the present application include a particular feature, structure, or characteristic described in conjunction with the embodiment. Thus, the expressions “in one embodiment”, “in some embodiments”, “in other embodiments”, “in some other embodiments”, etc. appearing in different places in this specification are not necessarily all referring to the same embodiment, but mean “one or more, but not all, embodiments”, unless otherwise specifically emphasized. The terms “include”, “comprise”, “have”, and variants thereof mean “include but not limited to”, unless otherwise specifically emphasized. The expression “a plurality of” means two or more.

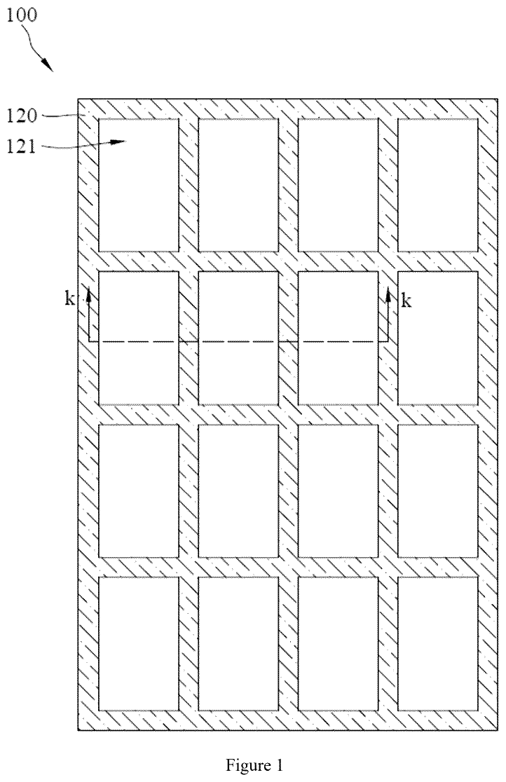

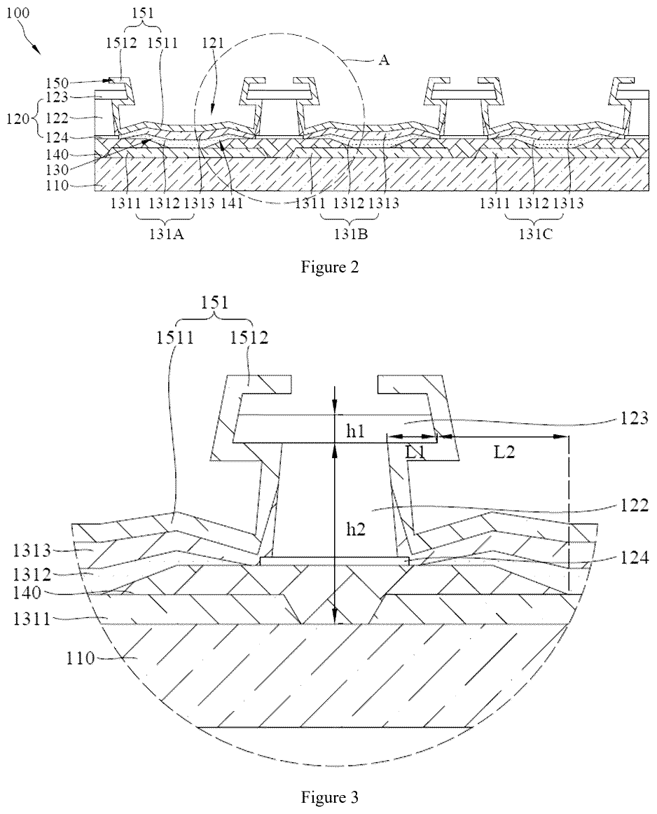

In order to at least partially solve the problem in the related art, referring to FIG. 1 and FIG. 2, an embodiment of the present application provides an array substrate including a substrate 110 and an isolation structure 120.

The substrate 110 is configured to support and carry other film layers in the array substrate. For example, the substrate 110 may be made of glass, polyimide (PI), or other materials.

The isolation structure 120 is arranged on a side of the substrate 110, the isolation structure 120 encloses isolation openings 121, and the isolation structure 120 can enclose isolation openings 121 for at least partially accommodating light-emitting units to complete the arrangement and formation of the light-emitting units without the aid of a mask. The isolation structure 120 may be arranged between two adjacent light-emitting units in a part of the light-emitting layer, or the isolation structure 120 may be arranged between every two adjacent light-emitting units. The specific structural form of the isolation structure 120 is not limited, as long as it can function to separate two light-emitting units.

The composition, preparation, and the like of the isolation structure 120 are further described in Patent No. CN 118251982 A, Patent No. 202410864269.8, Patent No. PCT/CN2024/098407, Patent No. PCT/CN2024/102783, Patent No. PCT/CN2024/098217, Patent No. PCT/CN2024/099419, and Patent No. PCT/CN2024/099072 for reference.

In one embodiment, the isolation structure 120 includes an isolation body 122 and a blocking portion 123 arranged in a stacked manner, where the blocking portion 123 is located on a side of the isolation body 122 away from the substrate 110, and an orthographic projection of the isolation body 122 on the substrate 110 is located within an orthographic projection of the blocking portion 123 on the substrate 110.

That is, the isolation structure 120 includes an isolation body 122 and a blocking portion 123 that are relatively independent of each other, where the isolation body 122 is located on the substrate 110, and the blocking portion 123 is arranged on the isolation body 122 in a stacked manner. In addition, an area covered by an orthographic projection of the blocking portion 123 on the substrate 110 is relatively large, while an area covered by an orthographic projection of the isolation body 122 on the substrate 110 is relatively small, and the orthographic projection of the blocking portion 123 on the substrate 110 can cover the orthographic projection of the isolation body 122 on the substrate 110. The isolation body 122 and the blocking portion 123 may have a regular cross-section shape, such as a rectangle, a triangle, etc., or an irregular cross-section shape.

In order to avoid deformation of the blocking portion 123 during the processing and manufacturing process, the isolation body 122 and the blocking portion 123 meet the following relation: h1/L1≥0.1, where h1 is a dimension of the blocking portion 123 in a direction perpendicular to a surface of the substrate 110; and L1 is a dimension of the blocking portion 123 protruding from the isolation body 122 in a direction parallel to a contact surface between the blocking portion 123 and the isolation body 122. It may be understood that h1 is a thickness dimension of the blocking portion 123, and L1 is a length dimension of the isolation body 122.

That is, in addition to having a portion connected to the isolation body 122, the blocking portion 123 also has a portion protruding from the isolation body 122 on the contact surface between the blocking portion 123 and the isolation body 122, and the length dimension of the portion of the blocking portion 123 protruding from the isolation body 122 is L1. Suppose h1/L1 ≥0.1, i.e., the thickness of the blocking portion 123 is relatively large, while the length of the blocking portion 123 protruding from the isolation body 122 is relatively small, the structural stability of the isolation body 122 and the blocking portion 123 are greater, which can effectively avoid deformation of the blocking portion 123 during subsequent processing processes.

In some embodiments, the ratio between the thickness dimension h1 of the blocking portion 123 and the length dimension L1 of the blocking portion 123 protruding from the isolation body 122 may be 0.2, 0.25, 0.3, 0.36, 0.45, etc. The above-mentioned description is merely an example of the ratio between the thickness dimension h1 of the blocking portion 123 and the length dimension L1 of the blocking portion 123 protruding from the isolation body 122, and in a practical embodiment, the ratio between the thickness dimension h1 of the blocking portion 123 and the length dimension L1 of the blocking portion 123 protruding from the isolation body 122 may be other values meeting the above range.

In the array substrate according to the embodiments of the present application, the isolation body 122 and the blocking portion 123 in the isolation structure 120 are made to meet the above-mentioned relation, and the thickness of the blocking portion 123 is relatively large, while the length of the blocking portion 123 protruding from the isolation body 122 is relatively small, and the structural stability of the isolation body 122 and the blocking portion 123 is greater. This can effectively avoid deformation of the blocking portion 123 in subsequent processing processes, and the structure of the isolation openings 121 enclosed by the isolation structure 120 is more stable, to prevent the display effect from being affected by the deformation of film layers.

It should be noted that the array substrate further includes a pixel circuit configured to control light-emitting units required to emit light at the right time, and may further include a drive circuit configured to drive the light-emitting units to emit light, etc.

On the basis of the above embodiments, in order to facilitate the processing and manufacturing of the isolation body 122 and the blocking portion 123, in some embodiments, in one embodiment, the isolation body 122 and the blocking portion 123 further meet the following relation: h1/L1≤2.

In some embodiments, the ratio between the thickness dimension h1 of the blocking portion 123 and the length dimension L1 of the blocking portion 123 protruding from the isolation body 122 may be 0.5, 0.8, 1, 1.1, 1.2, 1.5, 1.7, 1.9, 2, etc. The above-mentioned description is merely an example of the ratio between the thickness dimension h1 of the blocking portion 123 and the length dimension L1 of the blocking portion 123 protruding from the isolation body 122, and in a practical embodiment, the ratio between the thickness dimension h1 of the blocking portion 123 and the length dimension L1 of the blocking portion 123 protruding from the isolation body 122 may be other values meeting the above range. Such setting facilitates the manufacturing of the array substrate and the display panel 100 while meeting the structural stability of the isolation body 122 and the blocking portion 123.

In addition, in some other embodiments, the isolation body 122 and the blocking portion 123 further meet the following relation: On the contact surface between the blocking portion 123 and the isolation body 122, the length dimension L1 of the blocking portion 123 protruding from the isolation body 122 is less than or equal to 1μm. In some embodiments, the length dimension L1 of the blocking portion 123 protruding from the isolation body 122 may be 0.2 μm, 0.25 μm, 0.3 μm, 0.45 μm, 0.5 μm, 0.75 μm, 0.9 μm, 1 μm, etc. The above-mentioned description is merely an example of the length dimension L1 of the blocking portion 123 protruding from the isolation body 122, and in a practical embodiment, the length dimension L1 of the blocking portion 123 protruding from the isolation body 122 may be other values meeting the above range. Such setting keeps the length dimension L1 of the blocking portion 123 protruding from the isolation body 122 from being too large, and facilitates the processing and manufacturing of the isolation structure 120 while meeting the normal function of the isolation structure 120.

On the basis that the ratio between the thickness dimension h1 of the blocking portion 123 and the length dimension L1 of the blocking portion 123 protruding from the isolation body 122 meets the above range, the thickness dimension h1 of the blocking portion 123 may be reasonably set within the range. For example, in some embodiments, in one embodiment, the thickness dimension h1 of the blocking portion 123 in the direction perpendicular to the surface of the substrate 110 is greater than or equal to 0.1 μm. In some embodiments, the thickness dimension h1 of the blocking portion 123 may be 0.1 μm, 0.25 μm, 0.3 μm, 0.45 μm, 0.5 μm, 0.75 μm, 0.9 μm, 1 μm, etc. The above-mentioned description is merely an example of the thickness dimension h1 of the blocking portion 123, and in a practical embodiment, the thickness dimension h1 of the blocking portion 123 may be other values meeting the above range.

Further, in some other embodiments, in one embodiment, the thickness dimension h1 of the blocking portion 123 is less than or equal to 0.5 μm. In this way, the thickness of the blocking portion 123 is set within a reasonable range, which can avoid the deformation of the blocking portion 123 during subsequent processing processes, and facilitates processing and manufacturing at the same time.

The specific structural form of the isolation structure 120 is not limited. As shown in FIG. 3, in some embodiments, in one embodiment, the isolation structure 120 further includes a base portion 124. The base portion 124 is located on a side of the isolation body 122 close to the substrate 110, and the orthographic projection of the isolation body 122 on the substrate 110 is located within an orthographic projection of the base portion 124 on the substrate 110.

That is, the area covered by the orthographic projection of the base portion 124 on the substrate 110 is relatively large, and the area covered by the orthographic projection of the isolation body 122 on the substrate 110 is relatively small, and the orthographic projection of the base portion 124 on the substrate 110 can cover the orthographic projection of the isolation body 122 on the substrate 110. In this way, the base portion 124, the isolation body 122, and the blocking portion 123 can form an undercut structure, which facilitates contact between the light-emitting units and side walls of the isolation structure 120, and enhances the tightness of adhesion between the light-emitting units and the isolation structure 120. Moreover, such a design also facilitates the processing and formation of the isolation structure 120, and can further improve the isolation performance of the isolation structure 120.

In some embodiments, in one embodiment, the dimension of the blocking portion 123 tends to decrease in a direction from the isolation body 122 to the blocking portion 123.

That is, on a side relatively close to the isolation body 122, the dimension of the blocking portion 123 is relatively large, and on a side relatively away from the isolation body 122, the dimension of the blocking portion 123 is relatively small. In other words, the dimension of the blocking portion 123 varies from large to small in the direction from the isolation body 122 to the blocking portion 123. Setting the blocking portion 123 to the above shape facilitates the subsequent processing and manufacturing of the film layers. In the embodiment shown in FIG. 3, the blocking portion 123 may have a cross-section shape of trapezoid, and the isolation body 122 may also have a cross-section shape of trapezoid. Such a design can facilitate the processing and formation of the isolation structure 120.

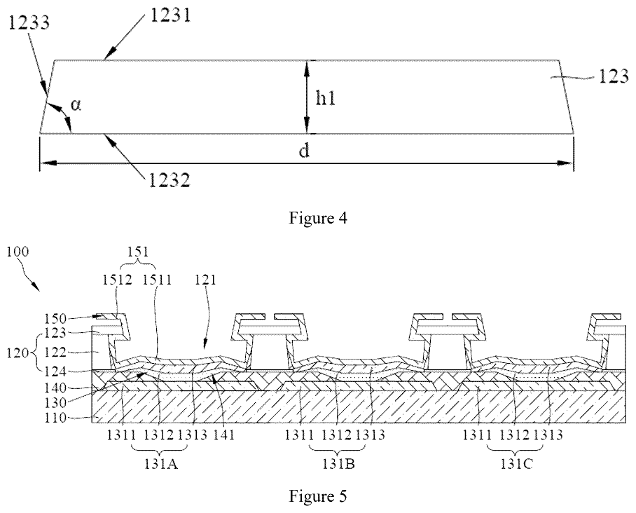

Referring to FIG. 3 in conjunction with FIG. 4, in some embodiments, in one embodiment, the blocking portion 123 includes a top surface 1231, a bottom surface 1232, and side wall surfaces 1233, where the top surface 1231 and the bottom surface 1232 are arranged opposite each other and spaced apart, the side wall surfaces 1233 are connected to the top surface 1231 and the bottom surface 1232, an orthographic projection of the top surface 1231 on the substrate 110 is located within an orthographic projection of the bottom surface 1232 on the substrate 110, and the blocking portion 123 meets the following relation: 70°≤α≤90°, where α is an included angle between the bottom surface 1232 and the side wall surface 1233.

The included angles α between the bottom surface 1232 and two side wall surfaces 1233 both meet the above relation when the two side wall surfaces 1233 of the blocking portion 123 are arranged symmetrically with respect to the bottom surface 1232 and the top surface 1231. The included angle α between the bottom surface 1232 and at least one of the two side wall surfaces 1233 meets the above relation when the two side wall surfaces 1233 of the blocking portion 123 are not arranged symmetrically with respect to the bottom surface 1232 and the top surface 1231. In some embodiments, the included angle α between the bottom surface 1232 and the side wall surface 1233 of the blocking portion 123 may be 70°, 72°, 75°, 80°, 85°, etc. The above-mentioned description is merely an example of the included angle α between the bottom surface 1232 and the side wall surface 1233 of the blocking portion 123, and in a practical embodiment, the included angle α between the bottom surface 1232 and the side wall surface 1233 of the blocking portion 123 may be other values meeting the above range. The included angle α between the bottom surface 1232 and the side wall surface 1233 of the blocking portion 123 is set to meet the above range, and the ratio of the length and the thickness of the blocking portion 123 can be reasonably controlled, and thus the length and the thickness are both within reasonable ranges.

In order to further avoid signal crosstalk between adjacent light-emitting units, in some embodiments, in one embodiment, the array substrate further includes a pixel defining layer 140. The pixel defining layer 140 is arranged on a side of the isolation structure 120 close to the substrate 110, the pixel defining layer 140 defines a plurality of pixel openings 141 arranged spaced from each other, the pixel openings 141 communicate with the isolation openings 121, and the light-emitting units are arranged corresponding to the pixel openings 141. The pixel defining layer 140 is disposed and the light-emitting units can be arranged to avoid signal crosstalk between adjacent light-emitting units.

In some embodiments, in one embodiment, a distance L2 between an edge of an orthographic projection of the pixel defining layer 140 on the substrate 110 and an edge of the orthographic projection of the blocking portion 123 on the substrate 110 is greater than or equal to 1 μm.

As shown in FIG. 2, the area covered by the orthographic projection of the pixel defining layer 140 on the substrate 110 is relatively large, and the area covered by the orthographic projection of the blocking portion 123 on the substrate 110 is relatively small, and the orthographic projection of the pixel defining layer 140 on the substrate 110 can cover the orthographic projection of the blocking portion 123 on the substrate 110. Moreover, the shortest distance between the edge of the orthographic projection of the pixel defining layer 140 on the substrate 110 and the edge of the orthographic projection of the blocking portion 123 on the substrate 110 is L2.

In some embodiments, the distance L2 between the edge of the orthographic projection of the pixel defining layer 140 on the substrate 110 and the edge of the orthographic projection of the blocking portion 123 on the substrate 110 may be 1 μm, 1.5 μm, 1.8 μm, 2 μm, 3 μm, 5 μm, etc. The above-mentioned description is merely an example of the distance L2 between the edge of the orthographic projection of the pixel defining layer 140 on the substrate 110 and the edge of the orthographic projection of the blocking portion 123 on the substrate 110, and in a practical embodiment, the distance L2 between the edge of the orthographic projection of the pixel defining layer 140 on the substrate 110 and the edge of the orthographic projection of the blocking portion 123 on the substrate 110 may be other values meeting the above range. The edge of the orthographic projection of the pixel defining layer 140 on the substrate 110 and the edge of the orthographic projection of the blocking portion 123 on the substrate 110 are set to meet the above relation, and the pixel defining layer 140 and the isolation structure 120 have a hierarchical arrangement in a direction parallel to the surface of the substrate 110, which can enhance the overall structural strength of the array substrate.

In some embodiments, in one embodiment, the isolation structure 120 and the pixel defining layer 140 meet the following relation: h2≥1 μm, where h2 is a distance between a surface of the pixel defining layer 140 close to the substrate 110 and the bottom surface 1232 of the blocking portion 123 in the direction perpendicular to the surface of the substrate 110.

In some embodiments, the distance h2 between the surface of the pixel defining layer 140 close to the substrate 110 and the bottom surface 1232 of the blocking portion 123 may be 1 μm, 1.5 μm, 1.8 μm, 2 μm, 3 μm, 5 μm, etc. The above-mentioned description is merely an example of the distance h2 between the surface of the pixel defining layer 140 close to the substrate 110 and the bottom surface 1232 of the blocking portion 123, and in a practical embodiment, the distance h2 between the surface of the pixel defining layer 140 close to the substrate 110 and the bottom surface 1232 of the blocking portion 123 may be other values meeting the above range. With such setting, a distance between the pixel defining layer 140 and the blocking portion 123 is relatively large, which is conducive to enhancing the structural stability of the isolation structure 120.

As described above, in addition to having a portion connected to the isolation body 122, the blocking portion 123 also has a portion protruding from the isolation body 122 on the contact surface between the blocking portion 123 and the isolation body 122. In some embodiments, in one embodiment, the blocking portion 123 includes a main body portion and a protruding portion, where the main body portion is arranged on a side of the isolation body 122 away from the substrate 110, and the protruding portion protrudes from the isolation body 122 relative to the main body portion in a direction close to the isolation opening 121. A distance between the main body portion and the substrate 110 is equal to a distance between the protruding portion and the substrate 110.

The portion of the blocking portion 123 that is connected to the isolation body 122 is the main body portion, and the portion of the blocking portion 123 that protrudes from the isolation body 122 on the contact surface between the blocking portion 123 and the isolation body 122 is the protruding portion. With such an arrangement, the main body portion and the protruding portion of the blocking portion 123 are arranged on a plane equidistant from the substrate 110, and the structure of the blocking portion 123 is flatter and more integral, which is conducive to enhancing the structural strength of the blocking portion 123.

Still referring to FIG. 1 and FIG. 2, based on the embodiments, an embodiment of the present application further provides an array substrate including a substrate 110 and an isolation structure 120.

The isolation structure 120 is arranged on a side of the substrate 110, the isolation structure 120 encloses the isolation openings 121, and the isolation structure 120 includes an isolation body 122 and a blocking portion 123 arranged in a stacked manner, where the blocking portion 123 is located on a side of the isolation body 122 away from the substrate 110, and an orthographic projection of the isolation body 122 on the substrate 110 is located within an orthographic projection of the blocking portion 123 on the substrate 110. The dimension h1 of the blocking portion 123 in the direction perpendicular to the surface of the substrate 110 is greater than or equal to 0.1 μm.

For the functions, structure, relative position, etc. of the substrate 110 and the isolation structure 120, reference may be made to the description in the above embodiments, which will not be repeated herein. In some embodiments, the thickness dimension h1 of the blocking portion 123 may be 0.1 μm, 0.25 μm, 0.3 μm, 0.45 μm, 0.5 μm, 0.75 μm, 0.9 μm, 1 μm, etc. The above-mentioned description is merely an example of the thickness dimension h1 of the blocking portion 123, and in a practical embodiment, the thickness dimension h1 of the blocking portion 123 may be other values meeting the above range.

In the array substrate according to the embodiments of the present application, the blocking portion 123 in the isolation structure 120 is made to meet the above-mentioned relation, and a thickness of the blocking portion 123 may be relatively large, and the structural stability of the blocking portion 123 is greater. This can effectively avoid deformation of the blocking portion 123 in subsequent processing processes, and the structure of the isolation openings 121 enclosed by the isolation structure 120 is more stable, to prevent the display effect from being affected by the deformation of film layers.

Further, in some other embodiments, in one embodiment, the dimension h1 of the blocking portion 123 in the direction perpendicular to the surface of the substrate 110 is less than or equal to 0.5 μm. In this way, the thickness of the blocking portion 123 is set within a reasonable range, which can avoid the deformation of the blocking portion 123 during subsequent processing processes, and facilitates processing and manufacturing at the same time.

On the basis that the thickness dimension h1 of the blocking portion 123 meets the above range, a ratio between the thickness dimension h1 of the blocking portion 123 and the length dimension L1 of the blocking portion 123 protruding from the isolation body 122 may be reasonably set within the range. For example, in some embodiments, in one embodiment, the isolation body 122 and the blocking portion 123 meet the following relation: h1/L1 ≥0.1, where L1 is a distance between an edge of an orthographic projection of a surface of the blocking portion 123 close to the isolation body 122 on the substrate 110 and an edge of an orthographic projection of a surface of the isolation body 122 close to the blocking portion 123 on the substrate 110.

In some embodiments, the ratio between the thickness dimension h1 of the blocking portion 123 and the length dimension L1 of the blocking portion 123 protruding from the isolation body 122 may be 0.2, 0.25, 0.3, 0.36, 0.45, etc. The above-mentioned description is merely an example of the ratio between the thickness dimension h1 of the blocking portion 123 and the length dimension L1 of the blocking portion 123 protruding from the isolation body 122, and in a practical embodiment, the ratio between the thickness dimension h1 of the blocking portion 123 and the length dimension L1 of the blocking portion 123 protruding from the isolation body 122 may be other values meeting the above range. With such setting, the thickness of the blocking portion 123 is relatively large, while the length of the blocking portion 123 protruding from the isolation body 122 is relatively small, the structural stability of the isolation body 122 and the blocking portion 123 are greater, which can effectively avoid deformation of the blocking portion 123 during subsequent processing processes.

An embodiment of the present application further provides a display panel 100. The display panel 100 includes the array substrate in any of the above embodiments and a light-emitting layer 130. The light-emitting layer 130 is arranged on a side of the array substrate, the light-emitting layer 130 includes a plurality of light-emitting units 131 arranged spaced from each other, and the light-emitting units 131 are arranged corresponding to the isolation openings 121.

The light-emitting units 131 in the light-emitting layer 130 may be red light-emitting units 131 configured to emit red light, green light-emitting units configured to emit green light, blue light-emitting units configured to emit blue light, white light-emitting units configured to emit white light, etc. The number of light-emitting units 131 of different types, the arrangement of the plurality of light-emitting units 131, the distance between two adjacent light-emitting units 131, etc. can be set flexibly, which is not limited herein. The light-emitting units 131 can emit light under the driving action of a drive circuit. In one embodiment, light-emitting materials in the light-emitting units 131 may emit light under the action of an electric field. The light-emitting unit 131 may include a first electrode 1311, a light-emitting portion 1312, and a second electrode 1313. An electric field can be generated under the action of the first electrode 1311 and the second electrode 1313, and the light-emitting portion 1312 can emit light under the driving of the electric field.

In the display panel 100 according to the embodiments of the present application, the isolation body 122 and the blocking portion 123 in the isolation structure 120 of the array substrate are made to meet the above-mentioned relation, to effectively avoid deformation of the blocking portion 123 in subsequent processing processes, and the structure of the isolation openings 121 enclosed by the isolation structure 120 is more stable, which facilitates the manufacturing of the light-emitting units 131, and prevents the display effect from being affected by the deformation of the film layers.

In some embodiments, in one embodiment, the light-emitting layer 130 includes a first light-emitting unit 131A, a second light-emitting unit 131B, and a third light-emitting unit 131C. Values of h1 /L1 in the isolation structure 120 are different from each other on a side of the first light-emitting unit 131A, on a side of the second light-emitting unit 131B, and on a side of the third light-emitting unit 131C.

That is, the value of h1/L1 in the isolation structure 120 on a side of the first light-emitting unit 131A is different from the value of h1/L1 in the isolation structure 120 on a side of the second light-emitting unit 131B, and is also different from the value of h1/L1 in the isolation structure 120 on a side of the third light-emitting unit 131C. In such a design, the values of h1/L1 in the isolation structure 120 are set for the first light-emitting unit 131A, the second light-emitting unit 131B, and the third light-emitting unit 131C, respectively, and this design has good applicability.

In some embodiments, in one embodiment, the light-emitting unit 131 includes a first electrode 1311, a light-emitting portion 1312, and a second electrode 1313 that are sequentially arranged in a stacked manner, and at least part of the first electrode 1311 is exposed from the pixel opening 141. An orthographic projection of the first electrode 1311 on the substrate 110 at least partially overlaps the orthographic projection of the isolation body 122 on the substrate 110.

As shown in FIG. 2, a part of the structure in the first electrode 1311 is exposed from the pixel opening 141, and another part of the structure may extend within the pixel defining layer 140 to a position below the isolation body 122. This design, in which the first electrode 1311 of the light-emitting unit 131 extends to a position below the isolation body 122, prevents the edge of the first electrode 1311 from affecting the height change of an upper film layer, which helps to ensure the display effect.

In some embodiments, in one embodiment, the display panel 100 further includes an encapsulation layer 150. The encapsulation layer 150 is arranged on a side of the light-emitting layer 130 away from the substrate 110, the encapsulation layer 150 includes a plurality of encapsulation units 151, and the encapsulation unit 151 is arranged corresponding to at least one of the light-emitting units 131.

The encapsulation layer 150 can encapsulate and protect the isolation structure 120 and the light-emitting units 131 as a whole, the encapsulation layer 150 may be a single-layer structure made of inorganic materials or organic materials, or may be a stacked structure made of at least one of inorganic materials or organic materials, which is not limited herein. The encapsulation layer 150 is arranged and the encapsulation units 151 can provide a better encapsulation effect on the isolation openings 121 and improve resistance of the encapsulation layer to moisture, which can avoid a problem that intrusion of moisture through the encapsulation layer 150 into the interior of the display panel 100 causes encapsulation failure, and can thus avoid dark spots in the display panel 100 and improve the display effect of the display panel 100.

In some embodiments, in one embodiment, the encapsulation unit 151 includes a body portion 1511 and an extension portion 1512 connected to each other, the body portion 1511 covers a surface of a side of the light-emitting unit 131 away from the substrate 110, the extension portion 1512 extends at least partially to a surface of a side of the blocking portion 123 away from the substrate 110, and an orthographic projection of the extension portion 1512 on the substrate 110 at least partially overlaps the orthographic projection of the isolation body 122 on the substrate 110.

Referring to FIG. 1 in conjunction with FIG. 5, in some embodiments, in one embodiment, the orthographic projection of the first electrode 1311 on the substrate 110 is located within the orthographic projection of the encapsulation unit 151 on the substrate 110.

Unlike the embodiment shown in FIG. 2, in this embodiment, the extension portion 1512 of the encapsulation unit 151 has a larger extension length in a direction away from the body portion 1511, and the extension portion 1512 covers a wider range. In this way, a coverage area of the orthographic projection of the encapsulation unit 151 on the substrate 110 is relatively large, while a coverage area of the orthographic projection of the first electrode 1311 on the substrate 110 is relatively small, and the orthographic projection of the encapsulation unit 151 on the substrate 110 can cover the orthographic projection of the first electrode 1311 on the substrate 110. Such setting helps to improve the stability of the encapsulation unit 151 and ensures the encapsulation effect.

In some embodiments, in one embodiment, the display panel 100 further includes a protective layer arranged on a side of the blocking portion 123 away from the substrate 110.

The protective layer may be made of a dry film layer that is less susceptible to deformation or has a small amount of deformation. The protective layer is arranged on the side of the blocking portion 123 away from the substrate 110, and the blocking portion 123 can be pressed hard, further avoiding deformation of the blocking portion 123.

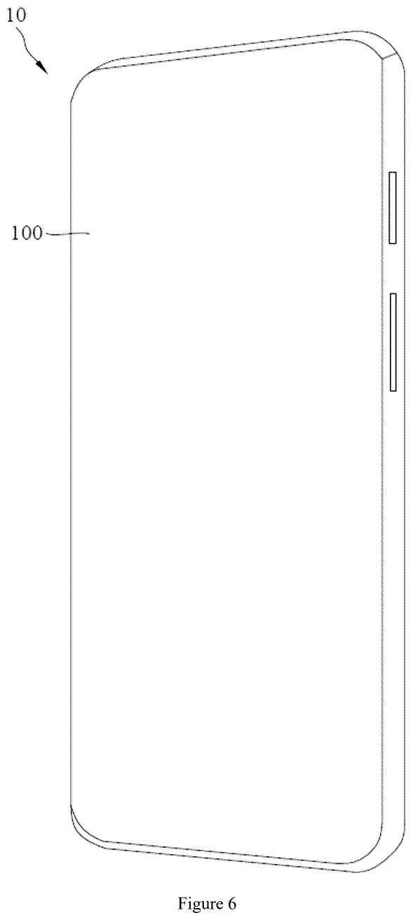

Referring to FIG. 1 to FIG. 5 and in conjunction with FIG. 6, an embodiment of the present application further provides a display apparatus 10. The display apparatus 10 includes a display panel 100 in any of the above embodiments.

The display panel 100 disclosed in the embodiment of the present application is applied to the display apparatus 10. The display apparatus 10 may be any product or component having a display function, including but not limited to a cell phone, a tablet computer, a laptop computer, an e-book reader, a wearable device, a remote control, a television, a desktop computer, an in-vehicle device, etc. to provide the function of screen display. Since the display panel 100 in any of the above embodiments is used, the isolation body 122 and the blocking portion 123 in the isolation structure 120 are made to meet the above-mentioned relation, and the thickness of the blocking portion 123 is relatively large, while the length of the blocking portion 123 protruding from the isolation body 122 is relatively small, and the structural stability of the isolation body 122 and the blocking portion 123 is greater. This can effectively avoid deformation of the blocking portion 123 in subsequent processing processes, and the structure of the isolation openings 121 enclosed by the isolation structure 120 is more stable, to prevent the display effect from being affected by the deformation of film layers.

In the above embodiments, the embodiments are described with different emphases, and for a part which is not detailed or described in an embodiment, reference may be made to the related description of the other embodiments.

The above embodiments are merely used for illustrating rather than limiting the embodiments of the present application. Although the present application has been illustrated in detail with reference to the foregoing embodiments, it should be understood that modifications may still be made to the solutions described in the foregoing embodiments, or equivalent replacements may be made to a part of the features. However, these modifications or substitutions do not make the essence of the corresponding solutions depart from the spirit and scope of the embodiments of the present application, and shall fall within the scope of protection of the present application.

1. An array substrate, comprising:
a substrate; and
an isolation structure arranged on a side of the substrate, the isolation structure enclosing isolation openings, and the isolation structure comprising an isolation body and a blocking portion arranged in a stacked manner, wherein the blocking portion is located on a side of the isolation body away from the substrate, an orthographic projection of the isolation body on the substrate is located within an orthographic projection of the blocking portion on the substrate, and the isolation body and the blocking portion meet the following relation: h1/L1≥0.1, wherein h1 is a dimension of the blocking portion in a direction perpendicular to a surface of the substrate; and L1 is a dimension of the blocking portion protruding from the isolation body in a direction parallel to a contact surface between the blocking portion and the isolation body.

2. The array substrate according to claim 1, wherein the isolation body and the blocking portion meet the following relation: h1/L1≤2.

3. The array substrate according to claim 1, wherein the dimension L1 of the blocking portion protruding from the isolation body in the direction parallel to the contact surface between the blocking portion and the isolation body is less than or equal to 1 μm.

4. The array substrate according to claim 1, wherein the dimension h1 of the blocking portion in the direction perpendicular to the surface of the substrate is greater than or equal to 0.1 μm, and
the dimension h1 of the blocking portion is less than or equal to 0.5 μm.

5. The array substrate according to claim 4, wherein the isolation structure further comprises a base portion, the base portion is located on a side of the isolation body close to the substrate, and the orthographic projection of the isolation body on the substrate is located within an orthographic projection of the base portion on the substrate.

6. The array substrate according to claim 1, wherein the dimension of the blocking portion tends to decrease in a direction from the isolation body to the blocking portion.

7. The array substrate according to claim 6, wherein the blocking portion comprises a top surface, a bottom surface, and side wall surfaces, wherein the top surface and the bottom surface are arranged opposite each other and spaced apart, the side wall surfaces are connected to the top surface and the bottom surface, an orthographic projection of the top surface on the substrate is located within an orthographic projection of the bottom surface on the substrate, and the blocking portion meets the following relation: 70°≤α≤90°,
wherein α is an included angle between the bottom surface and the side wall surface.

8. The array substrate according to claim 1, wherein the array substrate further comprises a pixel defining layer arranged on a side of the isolation structure close to the substrate, the pixel defining layer defines a plurality of pixel openings arranged spaced from each other, and the pixel openings communicate with the isolation openings.

9. The array substrate according to claim 8, wherein a distance L2 between an edge of an orthographic projection of the pixel defining layer on the substrate and an edge of the orthographic projection of the blocking portion on the substrate is not less than 1 μm.

10. The array substrate according to claim 8, wherein the isolation structure and the pixel defining layer meet the following relation: h2≥1 μm, wherein h2 is a distance between a surface of the pixel defining layer close to the substrate and the bottom surface of the blocking portion in the direction perpendicular to the surface of the substrate.

11. The array substrate according to claim 1, wherein the blocking portion comprises a main body portion and a protruding portion, wherein the main body portion is arranged on a side of the isolation body away from the substrate, the protruding portion protrudes from the isolation body in a direction close to the isolation openings relative to the main body portion, and a distance between the main body portion and the substrate is equal to a distance between the protruding portion and the substrate.

12. An array substrate, comprising:
a substrate; and
an isolation structure arranged on a side of the substrate, the isolation structure enclosing isolation openings, and the isolation structure comprising an isolation body and a blocking portion arranged in a stacked manner, wherein the blocking portion is located on a side of the isolation body away from the substrate, and an orthographic projection of the isolation body on the substrate is located within an orthographic projection of the blocking portion on the substrate,
wherein a dimension h1 of the blocking portion in a direction perpendicular to a surface of the substrate is greater than or equal to 0.1 μm.

13. The array substrate according to claim 12, wherein the dimension h1 of the blocking portion in the direction perpendicular to the surface of the substrate is less than or equal to 0.5 μm, and the isolation body and the blocking portion meet the following relation: h1/L1≥0.1, wherein L1 is a distance between an edge of an orthographic projection of a surface of the blocking portion close to the isolation body on the substrate and an edge of an orthographic projection of a surface of the isolation body close to the blocking portion on the substrate.

14. A display panel, comprising:
an array substrate according to claim 1; and
a light-emitting layer arranged on a side of the array substrate, wherein the light-emitting layer comprises a plurality of light-emitting units spaced apart from each other, and the light-emitting units are arranged corresponding to the isolation openings.

15. The display panel according to claim 14, wherein the light-emitting layer comprises a first light-emitting unit, a second light-emitting unit, and a third light-emitting unit; and values of h1/L1 in an isolation structure are different from each other on a side of the first light-emitting unit, on a side of the second light-emitting unit, and on a side of the third light-emitting unit.

16. The display panel according to claim 14, wherein the light-emitting unit comprises a first electrode, a light-emitting portion, and a second electrode that are sequentially arranged in a stacked manner in a direction from the array substrate to the light-emitting layer; and
an orthographic projection of the first electrode on the substrate at least partially overlaps the orthographic projection of the isolation body on the substrate.

17. The display panel according to claim 14, wherein the display panel further comprises an encapsulation layer arranged on a side of the light-emitting layer away from the substrate, the encapsulation layer comprises a plurality of encapsulation units, the encapsulation unit is arranged corresponding to at least one of the light-emitting units, the encapsulation unit comprises a body portion and an extension portion connected to each other, the body portion covers a surface of a side of the light-emitting unit away from the substrate, the extension portion extends at least partially to a surface of a side of the blocking portion away from the substrate, and an orthographic projection of the extension portion on the substrate at least partially overlaps the orthographic projection of the isolation body on the substrate.

18. The display panel according to claim 17, wherein an orthographic projection of the first electrode on the substrate is located within an orthographic projection of the encapsulation unit on the substrate.

19. The display panel according to claim 14, wherein the display panel further comprises a protective layer arranged on a side of the blocking portion away from the substrate.

20. A display apparatus, comprising:
a display panel, comprising:
a substrate; and
an isolation structure arranged on a side of the substrate, the isolation structure enclosing isolation openings, and the isolation structure comprising an isolation body and a blocking portion arranged in a stacked manner, wherein the blocking portion is located on a side of the isolation body away from the substrate, an orthographic projection of the isolation body on the substrate is located within an orthographic projection of the blocking portion on the substrate, and the isolation body and the blocking portion meet the following relation: h1/L1≥0.1, wherein h1 is a dimension of the blocking portion in a direction perpendicular to a surface of the substrate; and L1 is a dimension of the blocking portion protruding from the isolation body in a direction parallel to a contact surface between the blocking portion and the isolation body.
